(19) United States
(12) Patent Application Publication
(10) Pub. No.: US 2026/0310408 A1
(43) Pub. Date: Oct. 8, 2026

(54) METHOD AND APPARATUS FOR REPRESENTING DATA

(71) Applicant: SAMSUNG ELECTRONICS CO., LTD., Suwon-si (KR)

(72) Inventor: Hyeonuk SIM, Suwon-si (KR)

(73) Assignee: SAMSUNG ELECTRONICS CO., LTD., Suwon-si (KR)

(21) Appl. No.: 19/338,511

(22) Filed: Sep. 24, 2025

(30) Foreign Application Priority Data
Apr. 3, 2025 (KR) 10-2025-0043570

(51) Int. Cl. G06F 7/499; G06F 7/483

(52) U.S. Cl. CPC G06F 7/49915; G06F 7/483

(57) ABSTRACT

There is provided a method of and apparatus for representing data by setting level structures including individual levels by determining size ranges of target data, encoding, for all of the definable level structures, an exponent of the target data, and the exponent distinguishes each individual level, of the individual levels, forming a corresponding level structure of the level structures, determining, for all of the definable level structures, a first number of mantissa bits of the target data, the first number of mantissa bits corresponding to the each individual level forming the corresponding level structure, and calculating a level error corresponding to each of all of the definable level structures, and generating, based on the level error, a table including a final level structure, an encoded exponent corresponding to the final level structure, and a second number of mantissa bits corresponding to the final level structure.

### CROSS-REFERENCE TO RELATED APPLICATION

This application claims priority from Korean Patent Application No. 10-2025-0043570, filed on Apr. 3, 2025, in the Korean Intellectual Property Office, the disclosure of which is incorporated herein by reference in its entirety.

### BACKGROUND

### 1. Field

Methods and apparatuses consistent with embodiments relate to representing data.

### 2. Description of the Related Art

As various machine learning-based technologies, including an artificial neural network, are rapidly developing, securing the efficiency of the amount of computation and storage space for implementing such technologies is becoming an important technical task. In particular, in a large-scale neural network model, the number of trained parameters may exceed millions of units, and considerable resource consumption may occur in the process of storing and calculating these parameters.

To solve this problem, various compression techniques have been proposed, such as converting a floating-point (FP) format with high precision to a format with low precision or expressing the floating-point format with high precision by reducing the number of bits. For example, attempts to reduce memory usage and improve operation speed by converting FP32 to a format, such as FP16 or INT8, are actively being made. These techniques may be utilized to make a neural network model lightweight, especially in an embedded environment, a mobile device, and an edge computing environment.

The above information may be presented as a related art to help with the understanding of the disclosure. No arguments or decisions are raised to whether any of the above description is applicable as the prior art related to the present disclosure.

### SUMMARY

One or more embodiments may address at least the above problems and/or disadvantages and other disadvantages not described above. Also, the embodiments are not required to overcome the disadvantages described above, and an embodiment may not overcome any of the problems described above.

There is provided a method of representing data, the method including: setting, as definable level structures, a plurality of level structures including a plurality of individual levels by determining size ranges of target data; encoding, for all of the definable level structures, an exponent of the target data, and the exponent distinguishes each individual level, of the plurality of individual levels, forming a corresponding level structure of the plurality of level structures; determining, for all of the definable level structures, a first number of mantissa bits of the target data, the first number of mantissa bits corresponding to the each individual level forming the corresponding level structure; and calculating a level error corresponding to each of all of the definable level structures, and generating, based on the level error, a table including a final level structure, an encoded exponent corresponding to the final level structure, and a second number of mantissa bits corresponding to the final level structure.

Encoding the exponent of the target data may include building, based on a distribution of the target data, a tree representing the exponent distinguishing the each individual level forming the corresponding level structure.

Encoding the exponent may further include: determining a structure of the tree based on an appearance frequency set to the each individual level forming the corresponding level structure; and encoding the exponent by applying variable-length code to the each individual level by: assigning a first code length to the each individual level based on any of determining the appearance frequency to be greater than a frequency and determining the each individual level to have less than an amount of error, and assigning a long code length to the each individual level based on any of determining the appearance frequency to be less than the frequency and determining the each individual level to have more than the amount of error.

Determining the first number of mantissa bits may include: calculating an error-per-bit as inversely proportional to the first number of mantissa bits; and determining, based on a data size limit and the error-per-bit, the first number of mantissa bits as corresponding to the each individual level forming the corresponding level structure.

Determining the first number of mantissa bits may further include: increasing the first number of mantissa bits based on determining that the error-per-bit that is greater than a set error-per-bit; and repeatedly distributing a remaining bit based on the data size limit.

Generating the table may include generating the final level structure based on determining the level error to be minimized.

The target data may include a parameter of a trained artificial neural network model.

The method may further include: receiving input data; obtaining, based on the table, individual level information corresponding to the input data; obtaining encoded exponent information corresponding to the individual level information; obtaining information on a third number of mantissa bits corresponding to the individual level information; and converting the input data based on the encoded exponent information and the information on the third number of mantissa bits.

There is provided a method of representing data, the method including: setting, as definable level structures, a plurality of levels including a plurality of individual levels by determining size ranges of target data having a fixed length; based on a quantization error for each individual level forming a corresponding level structure, encoding, for all of the definable level structures, an exponent of the target data, and the exponent distinguishes each individual level, of the plurality of individual levels, forming the corresponding level structure; and calculating a level error corresponding to each of all of the definable level structures, and generating, based on the level error, a table including a final level structure and an encoded exponent corresponding to the final level structure.

Encoding the exponent may include: building, based on the quantization error for the each individual level forming the corresponding level structure, a tree representing the exponent distinguishing the each individual level forming the corresponding level structure; generating candidate nodes of the tree based on the quantization error for the each individual level forming the corresponding level structure; selecting, from among the candidate nodes, two nodes as having a least quantization error for the each individual level and integrating the two nodes into a parent node; and setting an error of the parent node to twice a sum of errors of child nodes.

The method may further include: producing, for all of the definable level structures, a number of mantissa bits that is automatically determined according to an exponent code length represented by the tree.

Generating the table may include generating the final level structure based on determining the level error to be minimized.

The target data may include a parameter of a trained artificial neural network model.

The method may further include: receiving input data; obtaining, based on the table, individual level information corresponding to the input data; obtaining encoded exponent information corresponding to the individual level information; obtaining information on a number of mantissa bits corresponding to the encoded exponent information; and converting the input data based on the encoded exponent information and the information on the number of mantissa bits.

There is provided an electronic device including: at least one processor including processing circuitry; and a memory storing instructions, and the instructions, when executed by the at least one processor individually or collectively, cause the electronic device to: set, as definable level structures, a plurality of levels including a plurality of individual levels by determining size ranges of target data; encode, for all of the definable level structures, an exponent of the target data, and the exponent distinguishes each individual level, of the plurality of individual levels, forming a corresponding level structure of the plurality of level structures; determine, for all of the definable level structures, a first number of mantissa bits of the target data, the first number of mantissa bits corresponding to the each individual level forming the corresponding level structure; and calculate a level error corresponding to each of all of the definable level structures, and generating based on the level error, a table including a final level structure, an encoded exponent corresponding to the final level structure, and a second number of mantissa bits corresponding to the final level structure.

The instructions, when executed by the at least one processor individually or collectively, may further cause the electronic device to build, based on a distribution of the target data, a tree representing the exponent distinguishing the each individual level forming the corresponding level structure.

The instructions, when executed by the at least one processor individually or collectively, may further cause the electronic device to: determine a structure of the tree based on an appearance frequency set to the each individual level forming the corresponding level structure; and encode the exponent by applying variable-length code to the each individual level by: assigning a first code length to with the each individual level based on any of determining the appearance frequency to be greater than a frequency and determining the each individual level to have less than an amount of error, and assigning a second code length to the each individual level based on any of determining the appearance frequency to be less than the frequency and determining the each individual level to have more than the amount of error.

The instructions, when executed by the at least one processor individually or collectively, may further cause the electronic device to: calculate an error-per-bit as inversely proportional to a quantity of bits represented by the first number of mantissa bits; and determine, based on a data size limit and the error-per-bit, the first number of mantissa bits as corresponding to the each individual level forming the corresponding level structure,.

The instructions, when executed by the at least one processor individually or collectively, may further cause the electronic device to: increase the first number of mantissa bits based on determining that the error-per-bit that is greater than a set error-per-bit; and repeatedly distribute a remaining bit based on the data size limit.

### BRIEF DESCRIPTION OF THE DRAWINGS

The above and/or other aspects will be more apparent by describing certain embodiments, taken in conjunction with the accompanying drawings, in which:

FIG. 1 is a diagram illustrating a process of converting input data according to one or more embodiments;

FIGS. 2A and 2B are diagrams illustrating a data representation method according to one or more embodiments;

FIG. 3 is a flowchart illustrating a data representation method according to one or more embodiments;

FIG. 4 is a diagram illustrating an example of a configuration of a level structure and an individual level, according to one or more embodiments;

FIG. 5 is a diagram illustrating an example of a configuration of a Huffman tree and a process of encoding an exponent based on the Huffman tree, according to one or more embodiments;

FIG. 6 is a diagram illustrating tables generated according to one or more embodiments;

FIG. 7 is a flowchart illustrating an example of a process of generating a table in a variable-length data format, according to one or more embodiments;

FIG. 8 is a flowchart illustrating a data representation method according to one or more embodiments;

FIG. 9 is a diagram illustrating an example of a configuration of an error-weighted tree and a process of encoding an exponent based on the error-weighted tree, according to one or more embodiments;

FIG. 10 is a flowchart illustrating an example of a process of generating a table in a fixed-length data format, according to one or more embodiments;

FIG. 11 is a flowchart illustrating a process of generating an error-weighted tree, according to one or more embodiments;

FIG. 12 is a diagram illustrating a method of calculating data using a floating-point multiply and accumulate unit when input data is formed in a variable-length data format or a fixed-length data format, according to one or more embodiments;

FIG. 13 is a diagram illustrating an example of a configuration of a method of performing an operation by applying a data format of the present disclosure in a smartphone application processor (AP) or a system-on-chip (SoC), according to one or more embodiments; and

FIG. 14 is a diagram illustrating an electronic device according to one or more embodiments.

### DETAILED DESCRIPTION

The following structural or functional descriptions are exemplary to merely describe the embodiments, and the scope of the embodiments is not limited to the descriptions provided in the present specification. Various changes and modifications may be made thereto by those of ordinary skill in the art.

Although terms such as “first” or “second” are used to explain various components, the components are not limited to the terms. These terms should be used only to distinguish one component from another component. For example, a first component may be referred to as a second component, and similarly the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component. On the contrary, it should be noted that if it is described that one component is “directly connected”, “directly coupled”, or “directly joined” to another component, a third component may be absent. Expressions describing a relationship between components, for example, “between”, directly between“, or “directly neighboring”, etc., should be interpreted to be alike.

The singular forms “a”, “an”, and “the” are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined, all terms, including technical and scientific terms, used herein have the same meaning as commonly understood by one of ordinary skill in the art to which the present disclosure pertains. Terms, such as those defined in commonly used dictionaries, should be construed to have meanings matching with contextual meanings in the relevant art, and are not to be construed to have an ideal or excessively formal meaning unless otherwise defined herein.

The embodiments may be implemented as various types of products such as, for example, a personal computer, a laptop computer, a tablet computer, a smart phone, a television, a smart home appliance, an intelligent vehicle, a kiosk, and a wearable device. Hereinafter, embodiments will be described in detail with reference to the accompanying drawings. In the drawings, like reference numerals are used for like elements.

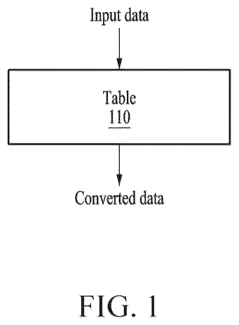

FIG. 1 is a diagram illustrating a process of converting input data according to one or more embodiments.

Referring to FIG. 1, the input data according to one or more embodiments may be numeric data that requires a conversion for an operation, storage, or communication. For example, the input data may include a parameter (e.g., weight or activation) of a trained artificial neural network model. The parameter of the artificial neural network model may have various characteristics depending on a network structure, a type of layer, a training method, or the like. The input data is real-valued data that requires a conversion for an operation, storage, or communication, and during the conversion process, an exponent and a mantissa may be reconstructed or represented in a compressed form by a table 110.

A fixed format, such as a 16-bit floating point (FP16) and 8-bit FP (FP8), which is an existing data representation method, applies the same exponent and the same number of mantissa bits, regardless of the distribution of input data, so the representation efficiency may vary depending on the characteristics of data. For example, small values may mainly appear in a particular layer, while relatively large values may appear in other layers. The existing format does not reflect these differences and applies the same precision, so the existing format may not be optimized in terms of storage space utilization or operational efficiency.

The table 110 according to one or more embodiments may convert data by encoding the exponent and adjusting the number of mantissa bits by considering the characteristics of the input data (e.g., distribution characteristics of the input data). The table 110 may include a pre-generated data conversion rule, through which the input data may be converted into a more compressed form.

The process of encoding the exponent may refer to converting data of a particular range into single code. The encoding of the exponent may be implemented by distinguishing the size ranges of the input data and allocating variable-length code (Prefix Code) to each range. For example, the exponent of the input data may be converted into a particular bit sequence (e.g., “110,” “1011,” or the like) according to the size of each piece of input data through a rule stored in the table 110, and the bit sequence may be used as exponent code. Through this, the length of the exponent code may vary depending on the size of the data, and data of a particular size range may be converted into short code, while data of a different size range may be converted into relatively long code.

The process of determining the number of mantissa bits may refer to determining the length of the mantissa corresponding to each piece of exponent code. The determining of the number of mantissa bits may include a process of determining how precisely to represent a corresponding value for a particular input data range (i.e., particular exponent code). For example, the determining of the number of mantissa bits may be configured in such a way that more mantissa bits are allocated to a frequently appearing data range to represent the frequently appearing data range with high precision, and fewer mantissa bits are allocated to a relatively less important data range to increase storage efficiency.

The table 110 may have a structure including a rule for converting the exponent into variable-length code and the number of mantissa bits corresponding to each piece of exponent code. When the input data is given, the table 110 may determine the size range to which the input data belongs and convert the corresponding exponent into encoded code. Thereafter, the length of the mantissa (the number of bits) may be determined corresponding to the size range to which the input data belongs. The input data may be approximated in a manner in which only some bits of the mantissa are maintained and the remaining bit is truncated or rounded according to the determined length of the mantissa. The final converted data may be generated by combining the converted exponent code with the approximated mantissa bit. For example, when the input data is 0.125, the table 110 may identify the size range to which a corresponding value belongs and then convert the exponent to ‘110’ according to the predefined rule, so the mantissa may be determined to be 6 bits.

The table 110 may be generated by analyzing the distribution of weights or activations, which are trained in a particular neural network model, and the data that is converted based on the generated table 110 may be utilized in the process of storage or communication and may also be used directly in a neural network operation. For example, the data converted by the table 110 may be used in a multiplication operation of a neural network.

The method of utilizing the table 110 is not limited to a predetermined data representation method and may be applied to storage, communication, operations, or the like of various pieces of numeric data. For example, the method may be applied to numeric data used in image processing or signal processing, in addition to a parameter of a neural network model. The converted data may provide a data representation method suitable for a predetermined application.

The generating of the table 110 according to one or more embodiments may refer to a process of analyzing the distribution of target data and building a structure including information for performing a data conversion based on the distribution of the target data. The shape of the table 110 is not limited to a particular way. For example, the table 110 may be implemented in a tree structure, in this case, when the input data is given, the exponent code and the number of mantissa bits may be determined through a tree search. Additionally, the table 110 may be implemented in the form of a lookup table and may convert the input data according to predefined mapping information.

The structure of the table 110 may be determined in various ways depending on the implementation method or application environment. For example, a compressed table may be used for efficient operations in hardware, and when performing a software-based conversion, a more flexible mapping structure may be applied. Accordingly, the table 110 is not limited to a particular data structure and may be implemented in various ways.

The target data for building the table 110 may refer to a dataset used to optimize a conversion rule. The target data may be numeric data, such as a trained weight and activation of a neural network model, and may reflect the distribution of data that is mainly used in a particular application field. For example, a neural network model used in image processing may build the table 110, targeting the weight trained by the corresponding model based on a training dataset and the activation generated when an input is input to a trained model.

The target data is data that serves as a reference for generating a conversion rule, and the input data may be data that is converted by referring to the table 110 during the conversion process. The target data may be pre-collected sample data and may determine the exponent-encoding method and the number of mantissa bits of the table 110 by analyzing a distribution of the target data. Thereafter, the generated table 110 may be used to convert new input data.

For example, when the table 110 is built using the trained weight of a particular neural network model as the target data, the table 110 may then be used to compress weight data or, if necessary, convert the activation generated during inference. That is, the target data is data used to build the table 110, and the input data may be actual data that is converted by referring to the generated table 110.

Accordingly, the target data may directly affect the generation of the table 110, and the input data may have a relationship that the input data is data subject to the conversion rule of the generated table 110. Accordingly, the table 110 may be configured to reflect the distribution of the target data, so conversion efficiency may be maximized when the input data has a distribution similar to the target data.

The entity that performs the generation of the table 110 according to one or more embodiments may be a system or an electronic device. More specifically, a data processing device, a processor, a neural processing unit (NPU), a server, or the like, which include hardware and/or software that performs an operation for generating the table 110, may be the entities for generating the table 110.

For example, when the table 110 is built by analyzing the trained weight and activation of a particular neural network model, the generation of the table 110 may be performed in a server or a cloud environment that trains the neural network model. Additionally, since the table 110 may be generated based on statistics of training data, a data analysis device or a neural network training system may perform the generation of the table 110.

Furthermore, when the table 110 is generated in advance and utilized by a local device, the entity that generates the table 110 may be different from the entity that uses the table 110. For example, after the table 110 is generated in a cloud-based server, the generated table 110 may be used for an input data conversion in an edge device or a mobile device.

For ease of description, although the following description is based on the generation of the table 110 by an electronic device, this is only an example, and the generation of the table 110 is not necessarily performed by the electronic device. As described above, the generation of the table 110 may be performed by various systems or devices depending on a particular application environment.

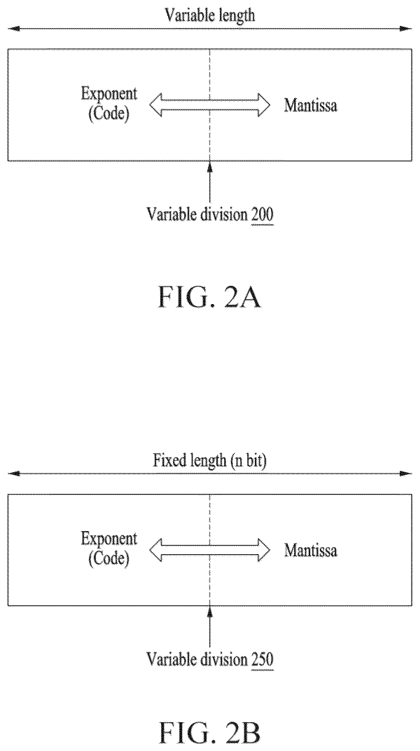

FIGS. 2A and 2B are diagrams illustrating a data representation method according to one or more embodiments. FIG. 2A is an example of a variable-length data format 200, and FIG. 2B is an example of a fixed-length data format 250. The description provided with reference to FIG. 1 may be substantially equally applied to FIGS. 2A and 2B.

Referring to FIG. 2A, the variable-length data format 200 according to one or more embodiments may be designed such that the length of the entire data is not fixed, and an exponent and the number of mantissa bits may be variably adjusted. Accordingly, data representation may be achieved by encoding the exponent and optimizing the number of mantissa bits according to the distribution of particular input data. That is, in the variable-length data format 200, the number of bits of exponent code may be determined through exponent encoding, and the number of mantissa bits may also be separately optimized and allocated. The number of mantissa bits may be determined to ensure data precision as much as possible at a particular level while considering the size limit of the entire data. For example, in a particular section, high precision may be provided by allocating a relatively longer mantissa bit, and in another section, a shorter mantissa bit may be allocated, thereby achieving efficient data representation.

Referring to FIG. 2B, in the fixed-length data format 250, the length of the entire data may be fixed, and when the number of bits to be allocated to the exponent is determined through exponent encoding, the number of mantissa bits may be determined to be remaining values, excluding the number of bits allocated to the exponent from the total number of bits. That is, instead of separately optimizing the number of mantissa bits, a value obtained by subtracting the length of the exponent code from the length of the entire data may be the number of mantissa bits. Accordingly, in the fixed-length data format 250, the process of encoding the exponent may directly affect the determination of the number of mantissa bits. For example, data to which short exponent code is assigned may have a relatively long mantissa bit, and conversely, data to which long exponent code is assigned may have a short mantissa bit.

Different methods of building a table according to each data representation method may be applied to the variable-length data format 200 according to FIG. 2A and the fixed-length data format 250 according to FIG. 2B. The variable-length data format 200 may include a process of encoding the exponent in a particular data size limit and determining the optimal number of mantissa bits. In the fixed-length data format 250, when the number of bits of exponent code is determined through exponent encoding, the number of mantissa bits may be automatically determined.

The variable-length data format 200 and the fixed-length data format 250 may be selectively applied according to a particular application method and may be utilized in various technical fields such as data storage, communication, operations, or the like. For example, the variable-length data format 200 may be used for data compression and efficient storage during the training process of a neural network model, and the fixed-length data format 250 may be used when a constant bit length must be maintained during the operation process.

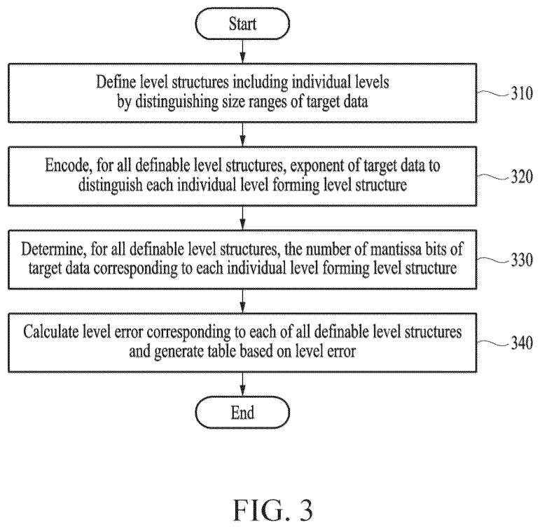

FIG. 3 is a flowchart illustrating a data representation method according to one or more embodiments. The description provided with reference to FIGS. 1, 2A, and 2B may be substantially equally applied to FIG. 3.

For ease of description, operation 310, operation 320, operation 330, and operation 340 are described as being performed using the electronic device described with reference to FIG. 1. However, operation 310, operation 320, operation 330, and operation 340 may be performed by another suitable electronic device in a suitable system.

The operations of FIG. 3 may be performed in the shown order and manner. However, the order of some operations may be changed or omitted without departing from the spirit and scope of the shown embodiment. The operations shown in FIG. 3 may be performed in parallel or simultaneously.

FIG. 3 illustrates a method of generating a table for converting input data into a variable-length data format (e.g., the variable-length data format 200 of FIG. 2A), according to one or more embodiments.

In operation 310, an electronic device according to one or more embodiments may define a plurality of level structures including a plurality of individual levels by distinguishing the size ranges of target data. The level structure according to one or more embodiments may indicate that the size ranges of the target data are divided into the plurality of individual levels and defined. Each individual level may include a range of a particular value and treat data within a corresponding range as the same level. The number of individual levels may be fixed to a particular value or adjusted according to the distribution characteristic of the data.

The individual levels may include ranges of particular values and may be determined in a unit of an exponential power of 2. That is, the section of an individual level may be defined in the form of a power of 2 and may have a range that increases or decreases by the multiple of an exponential power of 2 based on a particular reference value. For example, when the values of particular target data are distributed from −1 to 1, the level structure may include up to 2ⁿ−1 individual levels. Here, n may be the length (the number of bits) of the target data.

More specifically, the total number of individual levels used for encoding an exponent may be determined based on the length n (the number of bits) of the target data. For example, when an n bit may be allocated to the exponent, a total of 2ⁿ combinations may be possible. However, a subnormal region including an extremely small value near 0 may exist in the range of value represented by the exponent. The subnormal region may be needed to represent the smallest values separately from the general normalized levels so that one combination may be used as a level for a subnormal value.

When considering the subnormal value, the number of exponent levels that may be used in the normalized numeric representation may be 2ⁿ−1, excluding one corresponding to the subnormal region from the total number of combinations 2ⁿ. That is, even when all n bits allocated to the exponent are utilized, the number of normalized individual levels may be limited to 2ⁿ−1 because not all combinations of 2ⁿ are used as individual levels, and one is reserved for the subnormal representation.

Considering the constraint, for example, when n is 3 (i.e., n=3), 7 out of 8 combinations may be used as normalized levels, and the remaining one may be used as a subnormal level representing the smallest value. For example, when data has a minimum value close to 0, the subnormal level may be used to represent this approximately and may be applicable to both general variable-length and fixed-length data formats.

When the subnormal level is included as one individual level, the total number of individual levels may be 2ⁿ. This may be a method of defining all exponent code combinations that may be represented according to the total number of bits n and may be understood as a structure that utilizes all the exponent code spaces. That is, by including the subnormal level, each of all combinations of the exponent code from 000 to 111 may be configured to correspond to one individual level. Hereinafter, for ease of description, the subnormal level may also be treated as one individual level.

When there are eight individual levels, the smallest individual level may include a section with the smallest data value, and as an individual level increases thereafter, the size of the included data value may also gradually increase. For example, the first section of the individual level may include the range of [−1, −½], and the value range of a subsequent individual level may be subdivided into a unit that is twice as small as the previous individual level. That is, a second individual level may include the range of [−½, −¼], and a third individual level may include the range of [−¼, −⅛]. As such, the individual level may have a section that gradually decreases in a unit of an exponential power of 2.

The individual level may have a symmetrical structure with respect to positive and negative numbers, and the positive and negative number ranges may be set in the same way based on the center value. For example, when a particular individual level includes the range of [−⅛, 0], a corresponding positive number individual level may include the range of [0, ⅛]. As such, the individual level may be formed in an interval of an exponential power of 2, and the range of a value included in each individual level may be adjusted according to the number of individual levels and the distribution of the target data.

The number of individual levels may not be fixed. For example, eight individual levels may be appropriate for a particular data distribution, while five individual levels may be sufficient for another data distribution. In this case, a level structure that is more suitable for data distribution may be selected by adjusting the number of individual levels. For example, when values of the target data are concentrated in a particular section, a method of increasing precision by allocating more individual levels to a corresponding section and increasing storage efficiency by allocating fewer individual levels to a section with a relatively low appearance frequency may be applied.

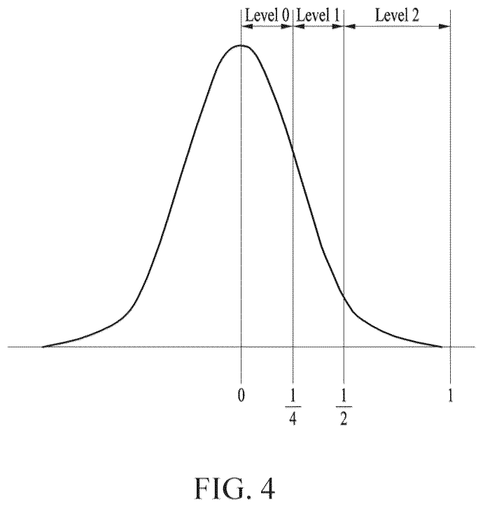

The level structure may include a combination of the individual levels, and the number and range of individual levels may be adjusted according to the characteristics of the data. When the level structure is determined, the exponent code and the number of mantissa bits for each individual level may be defined, so the data representation method may be designed to represent data efficiently. An example of the level structure is described in detail below with reference to FIG. 4.

In operation 320, the electronic device according to one or more embodiments may encode, for all definable level structures, the exponent of the target data to distinguish each individual level forming the level structure. The electronic device may build a tree that encodes the exponent to distinguish each individual level forming the level structure based on the distribution of the target data. The electronic device may determine a structure of the tree by considering the appearance frequency of each individual level forming the level structure and may encode the exponent by applying variable-length code to each individual level by assigning a short code length to a level with a high frequency or an individual level with a small error and assigning a long code length to a level with a low frequency or an individual level with a large error.

For example, the electronic device may apply the variable-length code (Prefix Code) according to the distribution of data values included in each individual level by considering the distribution characteristics of the target data. For exponent encoding, the electronic device may analyze the appearance frequency for each individual level and build the tree by allocating a short code length to a frequently appearing individual level and allocating a long code length to an individual level with a relatively low frequency or a low quantization error.

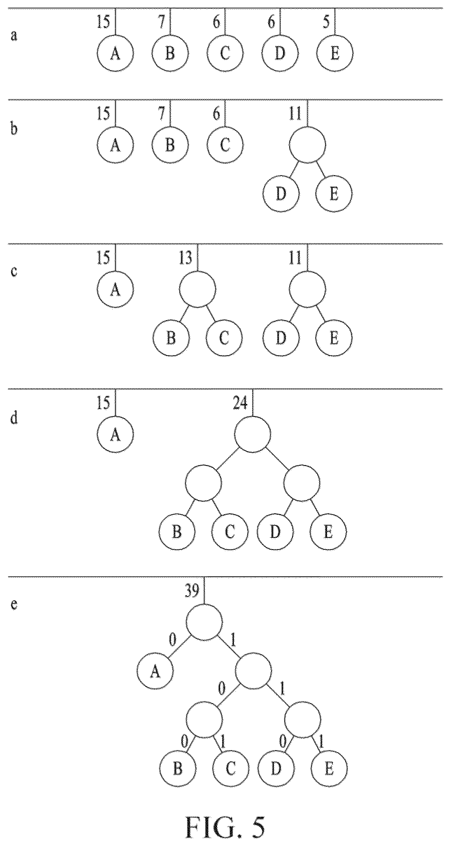

The electronic device may generate the tree based on a Huffman tree or an error-weighted tree to perform exponent encoding. The Huffman tree may be a method of generating optimal variable-length code based on the appearance frequency of each individual level and may minimize the overall code length by assigning short code to a frequently appearing individual level. For example, when a particular individual level appears most frequently in the target data, the code length representing the corresponding individual level may become short, while an individual level with a relatively low appearance frequency may have a longer code length. According to one or more embodiments, a method of determining the structure of the Huffman tree and encoding the exponent based on the tree structure is described in detail below with reference to FIG. 5.

Additionally, the electronic device may utilize the error-weighted tree to perform exponent encoding. The error-weighted tree may be a method of building the tree by considering the quantization error of the individual level, in addition to the appearance frequency. That is, the electronic device may analyze the quantization error of each individual level, assign a short code length to an individual level with a large quantization error, and assign a long code length to an individual level with a small quantization error. The error-weighted tree is a strategy to improve precision by assigning more mantissa bits in the section with a large quantization error and may be configured to minimize the overall average error in a situation in which the total number of bits is limited.

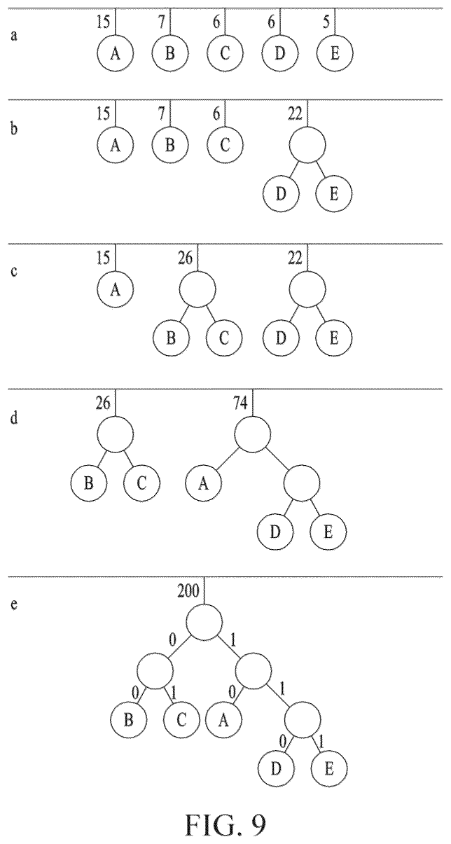

For example, when the quantization error of a particular individual level is relatively large, short exponent code may be assigned to the corresponding level so that the number of bits occupied by the exponent code in the total number of bits is reduced, and thus, more bits may be assigned to the mantissa. In contrast, an individual level with a small quantization error may require relatively less precision, so the number of mantissa bits may be reduced by being assigned longer exponent code. According to one or more embodiments, a method of determining the structure of the error-weighted tree and encoding the exponent based on the tree structure is described in detail below with reference to FIG. 9.

In operation 330, the electronic device according to one or more embodiments may determine, for all definable level structures, the number of mantissa bits of the target data corresponding to each individual level forming the level structure. The electronic device may adjust the balance between the precision of the overall data representation and the compression efficiency by variably assigning the length of the mantissa to each individual level.

All definable level structures according to one or more embodiments may refer to the entire set of the plurality of level structures that may be configured by dividing the value range of the target data into sections according to a predetermined reference. All definable level structures may include from a level structure including the maximum number of individual levels divided into the finest units to a level structure including a smaller number of individual levels configured by gradually merging some adjacent individual levels. For example, when reducing the number of level structures, two individual levels with the smallest range may be merged into one individual level. For example, in the 4 level structures described above, when two individual levels of [¼, ⅛] and [⅛] with the smallest range are merged into one, new 3 level structures may include the individual levels of [1, ½], [½, ¼], [½, ¼], and [¼-0].

When the number of mantissa bits is increased at each individual level forming the level structure, the electronic device may calculate an error per bit that is reducing and may determine the number of mantissa bits corresponding to each individual level forming the level structure based on the data size limit and error per bit. The electronic device may preferentially allocate a mantissa bit to an individual level with a large error per bit and repeatedly distribute the remaining bit in the data size limit.

More specifically, to determine the number of mantissa bits, the electronic device may evaluate the amount of quantization error that decreases when the number of mantissa bits is increased by 1 bit at each individual level. In this case, the calculated reduction amount may be defined as the error-per-bit reduction amount, and the corresponding value may vary depending on the correlation between the representative values of the individual levels and the number of mantissa bits.

For example, there may be an exponential function-like reduction pattern in which the quantization error is halved when the number of mantissa bits increases from 3 bits to 4 bits and the quantization error is halved again when the number of mantissa bits increases from 4 bits to 5 bits. Considering this, the initial few bits may have a large error reduction effect, but bits added later may have a relatively less effect.

The electronic device may evaluate the importance of each individual level based on the error-per-bit reduction amount and distribute the total bit budget to each individual level based on the evaluation result.

In particular, the electronic device may preferentially allocate the mantissa bit starting from an individual level with a large error-per-bit reduction amount by considering the total data size limit (e.g., the total bit number limit) for a given level structure. Thereafter, the overall structure may be repeatedly adjusted by redistributing the remaining bit. Such a process may be implemented as a greedy algorithm or a heuristic-based search method and may operate to minimize the average quantization error in the overall data representation.

The method of determining the number of mantissa bits may be adjusted according to data characteristics and statistical distribution and may also be used as base information for selecting, from among the plurality of level structures, a structure that achieves the lowest average error.

In operation 340, the electronic device according to one or more embodiments may calculate a level error corresponding to each of all definable level structures, and based on the level error, generate a table including a final level structure, an encoded exponent corresponding to the final level structure, and the number of mantissa bits corresponding to the final level structure.

The level error according to one or more embodiments may be an indicator of the total error that occurs when approximately representing the target data according to a particular level structure and may be produced by considering both the range division accuracy according to exponent encoding and the precision loss according to the number of mantissa bits. The level error may be produced, for example, by calculating the quantization errors of the target data belonging to each individual level and weighted-summing or accumulated-summing the errors. Here, the errors of each individual level may vary depending on the number of mantissa bits allocated to the corresponding level, that is, the residual precision.

The electronic device may calculate, for the plurality of level structures, the level error by combining the previously performed exponent-encoding result with the mantissa bit number determination result. For example, for each of a level structure including 8 individual levels, a level structure including 7 individual levels, . . . , a level structure including 2 individual levels, the overall quantization error when the corresponding structure is applied may be evaluated, and the structure showing the smallest level error among the level structures may be selected as the final level structure.

The electronic device may finally generate the table including the selected level structure, exponent-encoding information (e.g., variable-length code) corresponding to the corresponding level structure, and information on the number of mantissa bits. The table may be referenced during the subsequent input data conversion process and may include the following information for each individual level section, such as exponent code for a corresponding level (e.g., a bit string such as ‘101,’ ‘1100,’ or the like.), the number of mantissa bits corresponding to a corresponding level (e.g., 6 bits, 3 bits, or the like), and range information defining the start and end values of a corresponding section. The table is a kind of mapping information and may be used as a reference for determining which individual level section the corresponding data belongs to when the input data is given, encoding the exponent, and approximating the mantissas.

The generated table may be stored in the electronic device or may be transmitted to an external memory or other devices and utilized. Thereafter, when the input data is given, data conversion or compression may be performed based on the table. For example, when the table is generated based on the trained weight of a particular neural network model as the target data, the generated table may be used to perform a conversion by being applied to the weight or activation of a neural network, which are subsequently input.

FIG. 4 is a diagram illustrating an example of a configuration of a level structure and an individual level, according to one or more embodiments. The description provided with reference to FIGS. 1, 2A, 2B, and 3 may be substantially equally applied to FIG. 4.

The graph illustrated in FIG. 4 may represent, for example, input data or a distribution of target data, in which the horizontal axis may represent the size of data, and the vertical axis may represent the relative frequency or density of data having a corresponding size.

Referring to FIG. 4, the data may be distributed in the section between 0 and 1, have high density near the center, and have a form in which the density decreases toward both end portions. Based on the data distribution, an electronic device according to one or more embodiments may define a level structure. For example, FIG. 4 illustrates a level structure including three individual levels. Each individual level may be responsible for a portion of the size range of the data, and the individual levels may be indicated as Level 0, Level 1, and Level 2. Each individual level may include a predetermined section of a data value, which may be defined as a unit of an exponential power of 2.

Level 0 may include a section from 0 to ¼ and may be an individual level including data of the smallest size. Level 1 may include a section from ¼ to ½, and Level 2 may include a section from ½ to 1. The individual levels configured in this way may divide each data range into identifiable units, which may then be utilized to encode an exponent and determine a mantissa length.

The configuration of the individual levels may be adjusted depending on the distribution of the target data. For example, when the data is concentrated in the center, as shown in the distribution of FIG. 4, the center may be divided into more subdivided individual levels, and both end portions with a low frequency may form a relatively wide range into one individual level. Such a configuration may be a method of simultaneously considering efficiency and precision in data representation.

In addition, the ranges of the individual levels illustrated in FIG. 4 may follow an exponential function-based increasing or decreasing structure. For example, the section width of each level may be configured to be half that of the previous level, and this configuration may be utilized to simultaneously secure precise data section division and encoding efficiency.

The level structure illustrated in FIG. 4 is an example of a configuration, and the electronic device according to one or more embodiments may define a level structure having various numbers and ranges of individual levels depending on the characteristics of the target data. For example, a structure including 4, 8, or 16 individual levels may also be possible, and the section of each level may also be set nonlinearly.

In addition, in the level structure illustrated in FIG. 4, the individual levels may be defined only for the positive number range, but this is only an example, and the individual levels may be defined in the same manner for the negative number range. For example, even for the range from −1 to 0, the individual levels may be configured by setting a section in a unit of an exponential power of 2, and this configuration may be applied symmetrically to the positive number range.

FIG. 5 is a diagram illustrating an example of a configuration of a Huffman tree and a process of encoding an exponent based on the Huffman tree, according to one or more embodiments. The description provided with reference to FIGS. 1, 2A, 2B, and 4 may be substantially equally applied to FIG. 5.

FIG. 5 sequentially illustrates stage a, stage b, stage c, stage d, and stage e, and each stage may visually represent the intermediate result of the Huffman tree generation and the final encoding process. Stage a illustrates an appearance frequency corresponding to each individual level. A may be set to have a frequency of 15, B may be 7, C may be 6, D may be 6, and E may be 5. These frequencies may represent how often the corresponding individual level appears in target data and may be a reference for determining the length of code to be allocated to each individual level during the exponent-encoding process. In general, short code may be allocated to an individual level with a high frequency, and long code may be allocated to an individual level with a low frequency.

Stage b, stage c, and stage d of FIG. 5 illustrate the procedure for building the Huffman tree. In stage b, nodes D (6) and E (5) with the lowest frequency may be combined to generate a new node (11), and this node may include D and E as children. In stage c, nodes C (6) and B (7) with the next lowest frequency may be merged to form a new node (13), while the existing node (11) may be maintained without any change. In stage d, A (15), node (13), and node (11) may be merged into one tree to form a root node. The total weight of the root node may be 39, which may indicate the sum of the appearance frequencies of the entire data.

Stage e of FIG. 5 illustrates the exponent-encoding result corresponding to each individual level based on the completed Huffman tree. Code may be generated by allocating ‘0’ when moving from the root node to the left child node and by allocating ‘1’ when moving from the root node to the right child node. In this way, A may have code ‘0’ since A is located to the left of the root node. On the path, ‘100’ may be allocated to B, ‘101’ may be allocated to C, ‘100’ may be allocated to D, and ‘111’ may be allocated to E. As such, the code length for each individual level may be determined according to the appearance frequency, and short code may be assigned to the frequently appearing individual level.

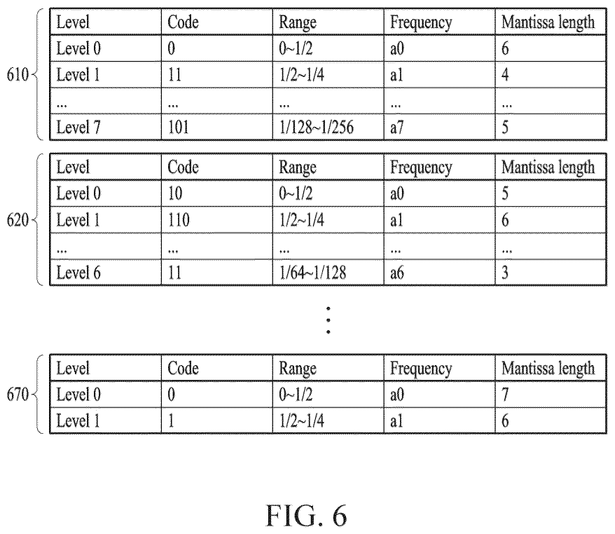

FIG. 6 is a diagram illustrating a table generation according to one or more embodiments. The description provided with reference to FIG. 1, FIG. 2A, FIG. 2B, FIG. 3, FIG. 4, and FIG. 5 may be substantially equally applied to FIG. 6.

FIG. 6 illustrates a plurality of tables (e.g., table 610, table 620, and to table 670), and each table may correspond to one level structure and may include exponent code, a range of values, an appearance frequency, and a mantissa length for each individual level forming a level structure.

A table 610 may be an example of a level structure including 8 individual levels (Level 0, Level 1, and to Level 7). Code may be assigned to each level to identify a corresponding level, and for example, code ‘0 ’ may be assigned to Level 0, code ‘11’ may be assigned to Level 1, and code ‘101’ may be assigned to Level 7. These pieces of code may correspond to an exponent and may be allocated in a variable-length code manner. The range may indicate the range of values that each level encompasses, and for example, Level 0 may include the range of [0, ½], Level 1 may include the range of [½, ¼], and Level 7 may include the range of [ 1/128, 1/256]. The ‘frequency’ may indicate the number or the ratio of the appearances of values belonging to the corresponding range within target data, and the ‘mantissa length’ may indicate the number of mantissa bits determined corresponding to each level. For example, a 6-bit mantissa may be allocated to Level 0, a 4-bit mantissa may be allocated to Level 1, and a 5-bit mantissa may be allocated to Level 7.

A table 620 may be an example of a level structure including 7 individual levels, and a table 670 may be an example of a level structure including 2 individual levels. Different numbers of levels, pieces of code, ranges, frequencies, and mantissa bits may be set for each table, which may be adjusted according to the distribution of the target data and constraints on the overall data representation length.

The plurality of tables (e.g., table 610, table 620, and to table 670) illustrated in FIG. 6 may be configured for each of a plurality of definable level structures, and an electronic device may calculate a level error corresponding to each level structure. The level error may refer to a quantization error or reconstruction error, which occurs when the entire data is represented by a combination of the corresponding level structure and the number of mantissa bits. The electronic device may calculate the total error of the entire level structure by aggregating the errors of the individual level units for each of the table 610, table 620, and to table 670 and may determine a table with the smallest total error to be the final table. The final table may then be used to perform a conversion on input data, and the conversion may be performed by referencing the corresponding exponent code and the number of mantissa bits in the table, depending on the value range to which the input data belongs.

In FIG. 6, for ease of description, it is described that the table is generated for each of all definable level structures and then the final table is selected from among the plurality of generated tables. However, in actual implementation, the level error for each level structure may be calculated, the final level structure may first be determined based on the calculated error, and then only one table corresponding to the final level structure may be generated.

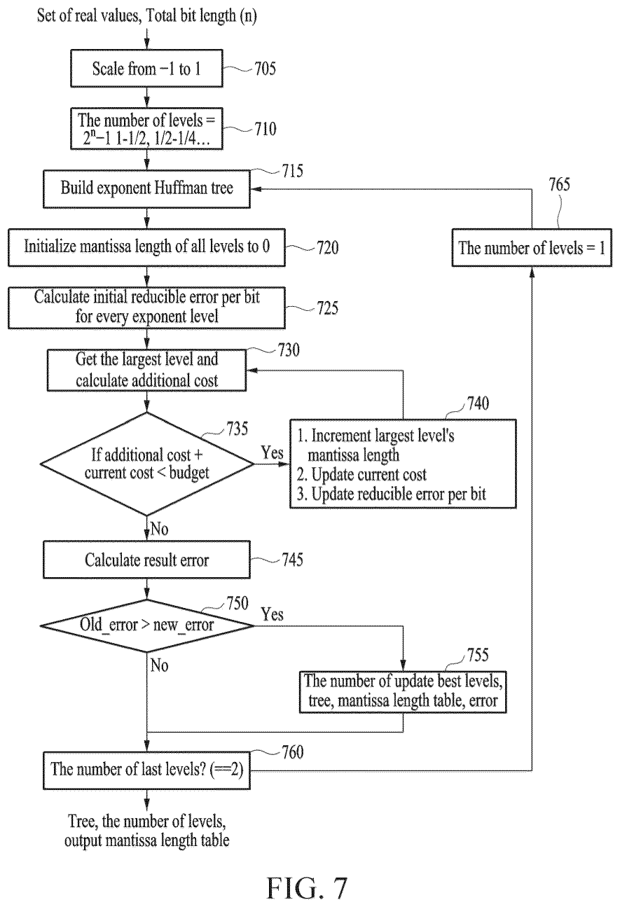

FIG. 7 is a flowchart illustrating an example of a process of generating a table in a variable-length data format, according to one or more embodiments. The description provided with reference to FIG. 1, FIG. 2A, FIG. 2B, FIG. 3, FIG. 4, FIG. 5, and FIG. 6 may be substantially equally applied to FIG. 7.

For ease of description, operation 705, operation 710, operation 715, operation 720, operation 725, operation 730, operation 735, operation 740, operation 745, operation 750, operation 755, operation 760, and operation 765 are described as being performed using the electronic device described with reference to FIG. 1. However, operation 705, operation 710, operation 715, operation 720, operation 725, operation 730, operation 735, operation 740, operation 745, operation 750, operation 755, operation 760, and operation 765 may also be performed by another suitable electronic device in a suitable system.

The operations of FIG. 7 may be performed in the shown order and manner. However, the order of some operations may be changed or omitted without departing from the spirit and scope of the shown embodiment. The operations shown in FIG. 7 may be performed in parallel or simultaneously.

In operation 705, an electronic device according to one or more embodiments may normalize real values of target data and may scale the real values to a range from −1 to 1. Scaling processing may be performed as a preprocessing process to secure the precision and operational efficiency of subsequent processing.

In operation 710, the electronic device may define a level structure based on the range of scaled data. For example, the electronic device may form a plurality of level structures by dividing the entire range into individual levels including sections of [1, ½], [½, ¼], [¼, ⅛], . . . by dividing the entire range into a unit of the power of 2 and combining these individual levels. The maximum number of levels may be set to 2ⁿ−1 (2ⁿ if a subnormal level is included as an individual level) depending on the total allowable number of bits n of the target data.

In operation 715, the electronic device may build a Huffman Tree to encode an exponent according to the currently defined level structure. The Huffman tree may be built by considering the appearance frequency of each individual level based on the distribution of the target data, and short length code may be assigned to an individual level with a high appearance frequency. Each individual level may be represented as a leaf node of a binary tree, and variable-length binary code may be determined depending on the path from a root node to each leaf node.

In operation 720, the electronic device may set the number of mantissa bits of all individual levels to 0 as an initial state. In operation 725, the electronic device may evaluate a reducible error per bit by calculating an error that is reduced when the number of mantissa bits is increased by 1 bit for each individual level. The reducible error per bit may be defined as a mean squared error between input data and approximated data or an error based on an absolute value.

In operation 730, an additional occurring cost may be calculated when an individual level with the largest error per bit is selected and the mantissa bit is increased by 1 bit at the individual level. In operation 735, it may be determined whether the total bit budget is exceeded by summing the additional cost and the total number of bits accumulated so far. Here, the bit budget may be related to the limit of the average number of bits of the entire data. For example, when the current error at a particular level is 0.5 and one mantissa bit is added, a value that may be represented at the corresponding level may be doubled so that the error may be reduced to about 0.25. As described above, as the number of mantissa bits increases, the error tends to decrease exponentially, so the electronic device may preferentially allocate a bit to a level with the largest error-per-bit reduction amount. This may be a method of achieving the maximum error reduction effect within a fixed budget.

When within the budget, the electronic device may increase the number of mantissa bits of the individual level selected from operation 740 by 1 and update the current total number of bits and error-per-bit information of each level. The electronic device may then return to operation 725 and repeat the bit distribution process.

In contrast, in operation 745, when the budget is exceeded, the final error for the currently built tree and the number of mantissa bits may be calculated without any further bit increase. In operation 750, the electronic device may compare the current final error with an old optimal error. In operation 755, the electronic device may update the optimal table configuration when the current final error is smaller than the old optimal error. Here, the optimal table configuration may be defined by the current number of levels, the Huffman tree, the number of mantissa bits corresponding to each individual level, and the final error value.

In operation 760, it may be determined whether the number of individual levels of the current level structure reaches 2, and if not, the number of levels may be reduced by 1 through operation 765, and the above process may be repeated. Finally, when the entire procedure of FIG. 7 is completed, the electronic device may output a table including the number of finally selected levels, the exponent tree structure, and the mantissa length information corresponding to each individual level.

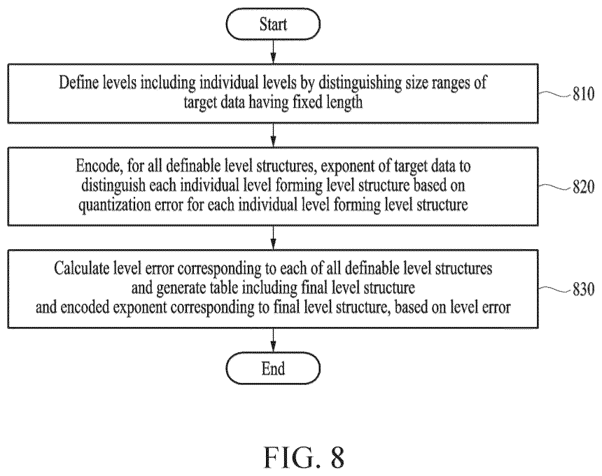

FIG. 8 is a flowchart illustrating a data representation method according to one or more embodiments. The description provided with reference to FIG. 1, FIG. 2A, FIG. 2B, FIG. 3, FIG. 4, FIG. 5, FIG. 6, and FIG. 7 may be substantially equally applied to FIG. 8.

For ease of description, operation 810, operation 820, and operation 830 are described as being performed using the electronic device described with reference to FIG. 1. However, operation 810, operation 820, and operation 830 may also be performed by another suitable electronic device in a suitable system.

The operations of FIG. 8 may be performed in the shown order and manner. However, the order of some operations may be changed or omitted without departing from the spirit and scope of the shown embodiment. The operations shown in FIG. 8 may be performed in parallel or simultaneously.

FIG. 8 illustrates a method of generating a table for converting input data into a fixed-length data format (e.g., the fixed-length data format 250 of FIG. 2B), according to one or more embodiments.

In operation 810, an electronic device according to one or more embodiments may define a plurality of levels including a plurality of individual levels by distinguishing the size ranges of target data having a fixed length.

In operation 820, the electronic device according to one or more embodiments may encode, for all definable level structures, an exponent of the target data to distinguish each individual level forming a level structure based on a quantization error for each individual level forming the level structure.

Exponent encoding may be performed based on the quantization error for each individual level, and here, the quantization error may be a value obtained by quantifying loss occurring when values at each level are approximated by representative values.

The electronic device may form a tree structure based on the quantization error for each individual level, thereby generating encoding code for exponent encoding. The tree may include a set of candidate nodes, and each node may include the quantization error for each individual level. The electronic device may select two nodes with the smallest quantization error, merge the two nodes into a parent node, and set the error of the parent node to twice the sum of the errors of child nodes. This method may be referred to as an error-weighted tree method, and the configuration of the entire tree may be optimized to maximize the efficiency of data representation by considering the quantization error.

In the fixed-length data format, the total number of bits of the entire data may be fixed, so when the exponent code is determined, the number of bits that may automatically be allocated to a mantissa may be limited. That is, when the code length for each level is determined as a result of the exponent encoding, the remaining bit obtained by subtracting the code length from the total number of bits may be allocated to the mantissa. Accordingly, the electronic device may automatically produce the number of mantissa bits according to the exponent code length determined through the tree without separate optimization.

In operation 830, the electronic device according to one or more embodiments may calculate a level error corresponding to each of all definable level structures, and based on the level error, generate a table including a final level structure and an encoded exponent corresponding to the final level structure. The electronic device may produce, for all definable level structures, the number of mantissa bits that is automatically determined according to the exponent code length represented by the tree.

FIG. 9 is a diagram illustrating an example of a configuration of an error-weighted tree and a process of encoding an exponent based on the error-weighted tree, according to one or more embodiments. The description provided with reference to FIG. 1, FIG. 2A, FIG. 2B, FIG. 3, FIG. 4, FIG. 5, FIG. 6, FIG. 7, and FIG. 8 may be substantially equally applied to FIG. 9.

FIG. 9 sequentially illustrates stage a, stage b, stage c, stage d, and stage e, and each stage may visually represent the intermediate result of the error-weighted tree generation and the final encoding process. Stage a illustrates an example of a situation in which the quantization error values for each of the individual levels A, B, C, D, and E are given as 15, 7,6, 6, and 5, respectively. Here, the quantization error may be a value obtained by quantifying an error from a representative value that occurs when input data is approximated in a predetermined manner in a section of a corresponding level. In stage b, D (6) and E (5) with the smallest error value may be selected and merged into one parent node, and the error of the parent node may be set to 22, which is calculated by multiplying the sum (6+5) of the errors of the child nodes by 2.

In stage c of FIG. 9, B (7) and C (6) with the next smallest error may be merged to form a new node, and the error of the corresponding node may be set to 26. In stage d, among A (15) and the previously merged node D-E (22), and node B-C (26), two nodes with the smallest sum of quantization errors may be selected and merged into upper nodes. Here, A may be merged with node D-E so that the error may be set to 74, and then node B-C may be finally merged with node A-D-E generated above so that a root node of the entire tree may be completed.

In stage e of FIG. 9, exponent-encoding code may be assigned based on the finally completed tree structure. Based on the path branching from the root node to the lower node, the final code for each individual level may be assigned by assigning 0 to the left branch and 1 to the right branch. For example, code ‘00’ may be assigned to Level B because Level B is located on a path that moves left twice from the root node, and code ‘10’ may be assigned to Level C because Level C is reached through a path that moves left from the root and then right. In the same way, ‘01’ may be assigned to A, ‘011’ may be assigned to D, and ‘111’ may be assigned to E. As described above, in the final stage of FIG. 9, the final code for exponent encoding may be determined from the error-weighted tree that is built based on the quantization error information of the individual level.

This method may be distinguished from the Huffman tree method in that the method builds the tree structure based on the quantization error rather than the appearance frequency. In the error-weighted tree method, it may be possible to preferentially allocate a bit to a level with high precision by allocating a short code length to an individual level with a large quantization error, and the total number of bits may be efficiently distributed by assigning a long code length to a level with a relatively small error and no problem with quantization.

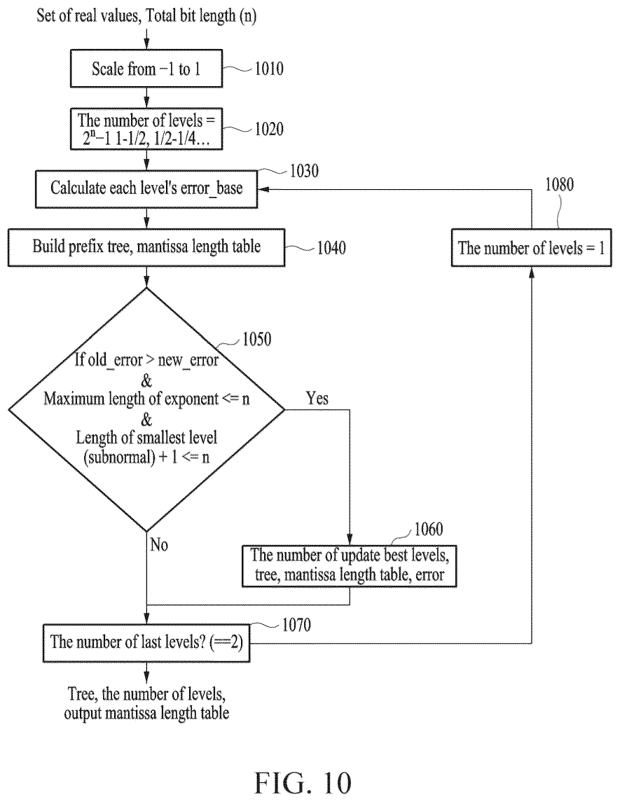

FIG. 10 is a flowchart illustrating an example of a process of generating a table in a fixed-length data format, according to one or more embodiments. The description provided with reference to FIG. 1, FIG. 2A, FIG. 2B, FIG. 3, FIG. 4, FIG. 5, FIG. 6, FIG. 7, FIG. 8, and FIG. 9 may be substantially equally applied to FIG. 10.

For ease of description, operation 1010, operation 1020, operation 1030, operation 1040, operation 1050, operation 1060, operation 1070, operation 1080 are described as being performed using the electronic device described with reference to FIG. 1. However, operation 1010, operation 1020, operation 1030, operation 1040, operation 1050, operation 1060, operation 1070, operation 1080 may also be performed by another suitable electronic device in a suitable system.

The operations of FIG. 10 may be performed in the shown order and manner. However, the order of some operations may be changed or omitted without departing from the spirit and scope of the shown embodiment. The operations shown in FIG. 10 may be performed in parallel or simultaneously.

In operation 1010, an electronic device according to one or more embodiments may normalize real values of target data and may scale the real values to a range from −1 to 1.

In operation 1020, the electronic device may define a level structure based on the range of scaled data. For example, the electronic device may form a plurality of level structures by dividing the entire range into individual levels including sections of [1, ½], [½, ¼], [¼, ⅛], . . . by dividing the entire range into the power of 2 and by combining these individual levels. The maximum number of levels may be set to 2ⁿ−1 (2ⁿ if a subnormal level is included as an individual level) depending on the total allowable number of bits n of the target data.

In operation 1030, the electronic device may calculate a base quantization error error_base for each individual level. The base quantization error error_base may refer to an error that occurs when all values in the corresponding section are approximated to one representative value when the number of mantissa bits at each individual level is 0, that is, when precision is not provided at all. The individual level may include a section (e.g., [½, ¼]) of a particular value, and all pieces of numeric data belonging to the corresponding range may share the same exponent code. Here, when the mantissa bit is not allocated, all pieces of data in the corresponding section may be approximated to a representative value (e.g., median value) of the corresponding section and stored.

In operation 1040, the electronic device may generate a prefix code tree based on the level structure defined in the previous stage and initialize or generate a mantissa length table based on the tree structure. The prefix code tree according to one or more embodiments may include an error-weighted tree, and which tree scheme is applied may vary depending on the level configuration strategy.

In operation 1050, the electronic device may determine whether the mantissa bit length+1 is less than or equal to the total number of bits n for the smallest level (subnormal) in which the total error new_error calculated from the current level structure is smaller than an old error old_error and the length of the longest exponent code in the tree is less than or equal to the total number of bits n. The smallest level is a range represented with the lowest precision and may be used as a condition that considers both securing precision and whether the overall budget is exceeded.

When all the conditions are satisfied, in operation 1060, the electronic device may update, to the best state so far, the current level number, the tree structure, the mantissa length table, and the total error value. In operation 1070, when it is determined whether the current number of levels is the last number of levels (e.g., 2), and if not, the electronic device may perform operation 1080, decrease the number or levels by 1, then return to operation 1030, and re-perform the processes from operations 1030 to 1070.

This repetitive process may be a method of generating various possible level structures, attempting to allocate the exponent and the mantissa to each level structure, and then selecting a combination with a minimum quantization error while satisfying the overall data size limit. The electronic device may compare the results at each repetition and repeat the update until the optimal combination is found.

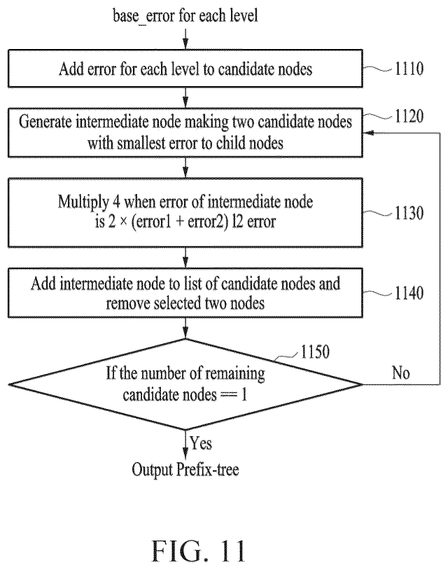

FIG. 11 is a flowchart illustrating a process of generating an error-weighted tree, according to one or more embodiments. The description provided with reference to FIG. 1, FIG. 2A, FIG. 2B, FIG. 3, FIG. 4, FIG. 5, FIG. 6, FIG. 7, FIG. 8, FIG. 9, and FIG. 10 may be substantially equally applied to FIG. 11.

For ease of description, operation 110, operation 1120, operation 1130, operation 1140, and operation 1150 are described as being performed using the electronic device described with reference to FIG. 1. However, operation 110, operation 1120, operation 1130, operation 1140, and operation 1150 may also be performed by another suitable electronic device in a suitable system.

The operations of FIG. 11 may be performed in the shown order and manner. However, the order of some operations may be changed or omitted without departing from the spirit and scope of the shown embodiment. The operations shown in FIG. 11 may be performed in parallel or simultaneously.

In operation 1110, the electronic device may add a base quantization error error_base calculated for each individual level to candidate nodes corresponding to each individual level. Each candidate node may correspond to one individual level and may include the size of the quantization error occurring at the corresponding individual level. For example, when the base quantization error error_base of Level 0 is 0.125 and the base quantization error error_base of Level 1 is 0.1, the candidate nodes corresponding to Level 0 and Level 1 may include error values of 0.125 and 0.1, respectively.

In operation 1120, the electronic device may select, from among the candidate nodes, two candidate nodes with the smallest quantization error value and generate one intermediate node including the two nodes as child nodes. The intermediate node is a node to build a tree of the upper structure and may have a new error value by reflecting the errors of lower nodes.

In operation 1130, the electronic device may calculate an error value of the generated intermediate node. The error value of the intermediate node may generally be set to twice the sum of the errors of the lower nodes. For example, when the error values of the two selected candidate nodes are error1 and error2, respectively, the error of the intermediate node may be calculated as 2×(error1+error2). When the error of the intermediate node is defined based on the L2 norm, the error of the intermediate node may be calculated by multiplying the sum of the errors of the child nodes by a coefficient of 4. That is, the error of the intermediate node may be set to 4×(error1+error2). This may be based on the mathematical characteristic that the L2 error is calculated as the sum of squared errors so that the depth-dependent effect is accumulated as a squared multiple.

In operation 1140, the electronic device may add the generated intermediate node to a list of candidate nodes and remove the two previously selected candidate nodes from the list. This process may be repeatedly performed until the number of remaining candidate nodes becomes one.

In operation 1150, it may be determined whether only one candidate node remains. When only one candidate node remains, the candidate node may be considered as a root node of the entire error-weighted tree.

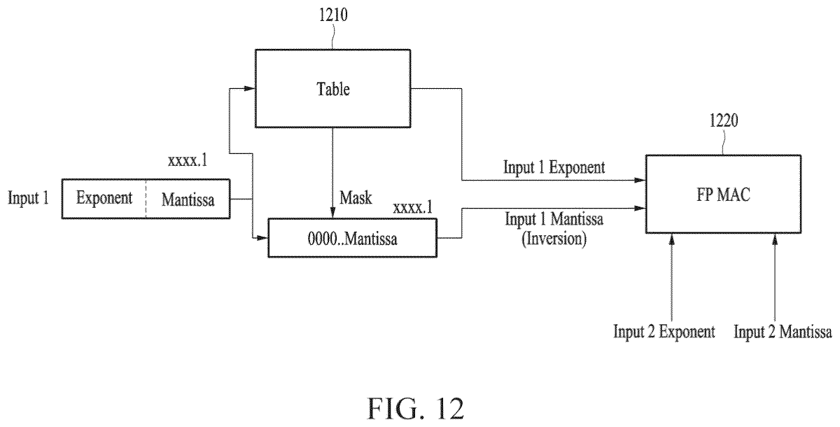

FIG. 12 is a diagram illustrating a method of calculating data using a floating-point multiply and accumulate unit when input data is formed in a variable-length data format or a fixed-length data format, according to one or more embodiments. The description provided with reference to FIG. 1, FIG. 2A, FIG. 2B, FIG. 3, FIG. 4, FIG. 5, FIG. 6, FIG. 7, FIG. 8, FIG. 9, FIG. 10, and FIG. 11 may be substantially equally applied to FIG. 12.

Referring to FIG. 12, input data input 1 may include an exponent and a mantissa, the exponent may be decoded by referring to a table 1210, and the mantissa may be restored in the normalized form after being masked by the number of bits corresponding to the exponent. Masking processing may be implemented by leaving only an actually valid bit in the entire mantissa of the input data and filling the remaining upper or lower bit with 0.

For example, when the input 1 is formed in a variable-length data format, the exponent may be encoded in variable-length code, and the table 1210 may include information on the number of mantissa bits corresponding to the exponent, in addition to the decoding result of the exponent. The electronic device may restore the exponent of the input 1 by referring to the table 1210, mask the mantissa of the input 1 according to the number of mantissa bits corresponding to the exponent, and then convert the mantissa of the input 1 into a normalized fixed-length mantissa. Here, the masked mantissa may be inverted and provided to an FP multiply and accumulate (MAC) 1220. The inversion processing may include correction according to a sign or may be a pre-conversion to match the characteristics of an integer operation circuit.

The FP MAC 1220 is an FP MAC unit, which may receive the exponent and mantissa of the input 1 and input 2 as inputs and perform a multiplication or accumulation operation. The FP MAC 1220 may perform a multiplication operation with the input 2 using the normalized exponent and mantissa of the input 1, and the result of the operation may be normalized if necessary and stored or used in subsequent operations.

The table 1210 may be formed in a structure that may quickly reference the actual exponent value corresponding to particular exponent code and the mantissa length. The table 1210 may be implemented in the form of a cache within a hardware circuit and may be applied with various access methods depending on the length of the exponent code. For example, the table 1210 may have a structure in which a table entry index is formed based on a particular bit pattern or an index decoding tree is embedded in hardware.

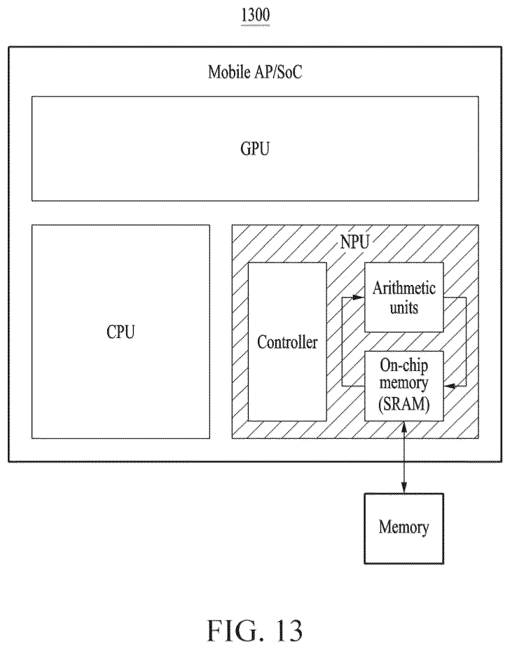

FIG. 13 is a diagram illustrating an example of a configuration of a method of performing an operation by applying a data format of the present disclosure in a smartphone application processor (AP) or a system-on-chip (SoC), according to one or more embodiments. The description provided with reference to FIG. 1, FIG. 2A, FIG. 2B, FIG. 3, FIG. 4, FIG. 5, FIG. 6, FIG. 7, FIG. 8, FIG. 9, FIG. 10, FIG. 11, and FIG. 12 may be substantially equally applied to FIG. 13.

As illustrated in FIG. 13, the mobile AP or SoC may be configured in a structure including a central processing unit (CPU), a graphics processing unit (GPU), and an NPU.

The NPU is a hardware block optimized for an artificial neural network operation and may include a controller, arithmetic units, and an on-chip memory (e.g., static random-access memory (SRAM)). The NPU may also be linked to an external memory and may be used to load a deep learning parameter or input data, which are required for an operation, into the on-chip memory or to store the operation result.

The arithmetic units may include an operation unit supporting a variable-length data format and/or a fixed-length data format, according to one or more embodiments. For example, the arithmetic units may perform a multiplication operation, a convolution operation, or the like by receiving a numeric format of a structure in which the exponent is encoded in variable-length code and the length of the mantissa is adjusted for each level, as described with reference to FIG. 1, FIG. 2A, FIG. 2B, FIG. 3, FIG. 4, FIG. 5, FIG. 6, FIG. 7, FIG. 8, FIG. 9, FIG. 10, FIG. 11, and FIG. 12.

The deep learning parameter may be stored as the converted state based on the numeric format described with reference to FIG. 1, FIG. 2A, FIG. 2B, FIG. 3, FIG. 4, FIG. 5, FIG. 6, FIG. 7, FIG. 8, FIG. 9, FIG. 10, FIG. 11, and FIG. 12, according to one or more embodiments. Here, the input data may have variable exponent and mantissa structures depending on the distribution of data, rather than a fixed structure, so the data may be represented more efficiently. This structure may increase energy efficiency by reducing the amount of data access during an operation, in addition to saving storage space in the on-chip memory.

Additionally, the NPU may have a structure that may flexibly adjust the trade-off between operation precision and memory usage. For example, high precision may be secured by allocating a long mantissa and short exponent code to a parameter region where the distribution is biased, and the overall operational efficiency and storage efficiency may be improved by applying a relatively short mantissa to a less important region. Such an operation may be realized through table-based exponent encoding and mantissa length referencing, which may be implemented by the table generation method and encoding method described above with reference to FIG. 3, FIG. 4, FIG. 5, FIG. 6, FIG. 7, FIG. 8, FIG. 9, FIG. 10, and FIG. 11.

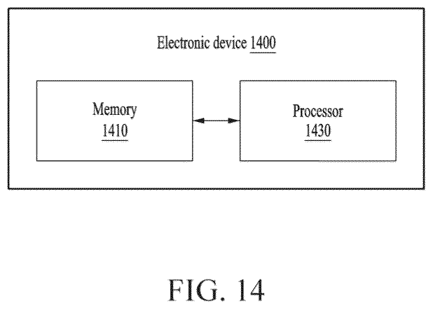

FIG. 14 is a diagram illustrating an electronic device according to one or more embodiments. The description provided with reference to FIG. 1, FIG. 2A, FIG. 2B, FIG. 3, FIG. 4, FIG. 5, FIG. 6, FIG. 7, FIG. 8, FIG. 9, FIG. 10, FIG. 11, FIG. 12 and FIG. 13 may substantially identically apply to FIG. 14.

Referring to FIG. 14, an electronic device 1400 may include a memory 1410 and a processor 1430. The electronic device 1400 according to one or more embodiments may include the electronic device described with reference to FIG. 1.

The memory 1410 may store instructions (or programs) executable by the processor 1430. For example, the instructions may include instructions for executing an operation of the processor 1430 and/or an operation of each component of the processor 1430.

The memory 1410 may be implemented as a volatile memory device or a non-volatile memory device.

The volatile memory device may be implemented as dynamic RAM (DRAM), SRAM, thyristor RAM (T-RAM), zero capacitor RAM (Z-RAM), or twin transistor RAM (TTRAM).

The non-volatile memory device may be implemented as electrically erasable programmable read-only memory (EEPROM), flash memory, magnetic RAM (MRAM), spin-transfer torque (STT)-MRAM, conductive bridging RAM(CBRAM), ferroelectric RAM (FeRAM), phase change RAM (PRAM), resistive RAM (RRAM), nanotube RRAM, polymer RAM (PoRAM), nano floating-gate memory (NFGM), holographic memory, molecular electronic memory device, or insulator resistance change memory.

The processor 1430 may process data stored in the memory 1410. The processor 1430 may execute computer-readable code (e.g., software) stored in the memory 1410 and instructions triggered by the processor 1430.

The processor 1430 may be a data-processing device implemented by hardware having a circuit that has a physical structure to execute desired operations. For example, the desired operations may include code or instructions included in a program.

For example, the data-processing device implemented by hardware may include a microprocessor, a CPU, a processor core, a multi-core processor, a multiprocessor, an application-specific integrated circuit (ASIC), and a field-programmable gate array (FPGA).

The processor 1430 may define a plurality of levels including a plurality of individual levels by distinguishing the size ranges of target data, encode, for all definable level structures, an exponent of the target data to distinguish each individual level forming a level structure, determine, for all definable level structures, the number of mantissa bits of the target data, which corresponds to each individual level forming the level structure, and calculate a level error corresponding to each of all definable level structures, and based on the level error, generate a table including a final level structure, an encoded exponent corresponding to the final level structure, and the number of mantissa bits corresponding to the final level structure. The processor 1430 may perform the operations described with reference to FIGS. 1 to 13 in substantially the same manner. Accordingly, a further description thereof is omitted herein.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, an FPGA, a programmable logic unit (PLU), a microprocessor or any other device capable of responding to and executing instructions in a defined manner. The processing device may run an operating system (OS) and one or more software applications that run on the OS. The processing device also may access, store, manipulate, process, and generate data in response to execution of the software. For purpose of simplicity, the description of a processing device is used as singular; however, one skilled in the art will appreciate that a processing device may include multiple processing elements and multiple types of processing elements. For example, a processing device may include multiple processors or a processor and a controller. In addition, different processing configurations are possible, such as parallel processors.

The software may include a computer program, a piece of code, an instruction, or combinations thereof, to independently or uniformly instruct or configure the processing device to operate as desired. Software and data may be embodied permanently or temporarily in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored in a non-transitory computer-readable recording medium.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as compact disc read-only memory (CD-ROM) discs and digital video discs (DVDs); magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher-level code that may be executed by the computer using an interpreter.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

What is claimed is:

1. A method of representing data, the method comprising:
setting, as definable level structures, a plurality of level structures comprising a plurality of individual levels by determining size ranges of target data;
encoding, for all of the definable level structures, an exponent of the target data, and the exponent distinguishes each individual level, of the plurality of individual levels, forming a corresponding level structure of the plurality of level structures;
determining, for all of the definable level structures, a first number of mantissa bits of the target data, the first number of mantissa bits corresponding to the each individual level forming the corresponding level structure; and
calculating a level error corresponding to each of all of the definable level structures, and generating, based on the level error, a table comprising a final level structure, an encoded exponent corresponding to the final level structure, and a second number of mantissa bits corresponding to the final level structure.

2. The method of claim 1, wherein encoding the exponent of the target data comprises building, based on a distribution of the target data, a tree representing the exponent distinguishing the each individual level forming the corresponding level structure.

3. The method of claim 2, wherein encoding the exponent further comprises:
determining a structure of the tree based on an appearance frequency set to the each individual level forming the corresponding level structure; and
encoding the exponent by applying variable-length code to the each individual level by:
assigning a first code length to the each individual level based on any of determining the appearance frequency to be greater than a frequency and determining the each individual level to have less than an amount of error, and
assigning a long code length to the each individual level based on any of determining the appearance frequency to be less than the frequency and determining the each individual level to have more than the amount of error.

4. The method of claim 1, wherein determining the first number of mantissa bits comprises:
calculating an error-per-bit as inversely proportional to the first number of mantissa bits; and
determining, based on a data size limit and the error-per-bit, the first number of mantissa bits as corresponding to the each individual level forming the corresponding level structure.

5. The method of claim 4, wherein determining the first number of mantissa bits further comprises:
increasing the first number of mantissa bits based on determining that the error-per-bit that is greater than a set error-per-bit; and
repeatedly distributing a remaining bit based on the data size limit.

6. The method of claim 1, wherein generating the table comprises generating the final level structure based on determining the level error to be minimized.

7. The method of claim 1, wherein the target data comprises a parameter of a trained artificial neural network model.

8. The method of claim 1, further comprising:
receiving input data;
obtaining, based on the table, individual level information corresponding to the input data;
obtaining encoded exponent information corresponding to the individual level information;
obtaining information on a third number of mantissa bits corresponding to the individual level information; and
converting the input data based on the encoded exponent information and the information on the third number of mantissa bits.

9. A method of representing data, the method comprising:
setting, as definable level structures, a plurality of levels comprising a plurality of individual levels by determining size ranges of target data having a fixed length;
based on a quantization error for each individual level forming a corresponding level structure, encoding, for all of the definable level structures, an exponent of the target data, and the exponent distinguishes each individual level, of the plurality of individual levels, forming the corresponding level structure; and
calculating a level error corresponding to each of all of the definable level structures, and generating, based on the level error, a table comprising a final level structure and an encoded exponent corresponding to the final level structure.

10. The method of claim 9, wherein encoding the exponent comprises:
building, based on the quantization error for the each individual level forming the corresponding level structure, a tree representing the exponent distinguishing the each individual level forming the corresponding level structure;
generating candidate nodes of the tree based on the quantization error for the each individual level forming the corresponding level structure;
selecting, from among the candidate nodes, two nodes as having a least quantization error for the each individual level and integrating the two nodes into a parent node; and
setting an error of the parent node to twice a sum of errors of child nodes.

11. The method of claim 10, further comprising:
producing, for all of the definable level structures, a number of mantissa bits that is automatically determined according to an exponent code length represented by the tree.

12. The method of claim 9, wherein generating the table comprises generating the final level structure based on determining the level error to be minimized.

13. The method of claim 9, wherein the target data comprises a parameter of a trained artificial neural network model.

14. The method of claim 9, further comprising:
receiving input data;
obtaining, based on the table, individual level information corresponding to the input data;
obtaining encoded exponent information corresponding to the individual level information;
obtaining information on a number of mantissa bits corresponding to the encoded exponent information; and
converting the input data based on the encoded exponent information and the information on the number of mantissa bits.

15. An electronic device comprising:
at least one processor including processing circuitry; and
a memory storing instructions,
wherein the instructions, when executed by the at least one processor individually or collectively, cause the electronic device to:
set, as definable level structures, a plurality of levels comprising a plurality of individual levels by determining size ranges of target data;
encode, for all of the definable level structures, an exponent of the target data, and the exponent distinguishes each individual level, of the plurality of individual levels, forming a corresponding level structure of the plurality of level structures;
determine, for all of the definable level structures, a first number of mantissa bits of the target data, the first number of mantissa bits corresponding to the each individual level forming the corresponding level structure; and
calculate a level error corresponding to each of all of the definable level structures, and generating based on the level error, a table comprising a final level structure, an encoded exponent corresponding to the final level structure, and a second number of mantissa bits corresponding to the final level structure.

16. The electronic device of claim 15, wherein the instructions, when executed by the at least one processor individually or collectively, further cause the electronic device to build, based on a distribution of the target data, a tree representing the exponent distinguishing the each individual level forming the corresponding level structure.

17. The electronic device of claim 16, wherein the instructions, when executed by the at least one processor individually or collectively, further cause the electronic device to:
determine a structure of the tree based on an appearance frequency set to the each individual level forming the corresponding level structure; and
encode the exponent by applying variable-length code to the each individual level by:
assigning a first code length to with the each individual level based on any of determining the appearance frequency to be greater than a frequency and determining the each individual level to have less than an amount of error, and
assigning a second code length to the each individual level based on any of determining the appearance frequency to be less than the frequency and determining the each individual level to have more than the amount of error.

18. The electronic device of claim 15, wherein the instructions, when executed by the at least one processor individually or collectively, further cause the electronic device to:
calculate an error-per-bit as inversely proportional to a quantity of bits represented by the first number of mantissa bits; and
determine, based on a data size limit and the error-per-bit, the first number of mantissa bits as corresponding to the each individual level forming the corresponding level structure,.

19. The electronic device of claim 18, wherein the instructions, when executed by the at least one processor individually or collectively, further cause the electronic device to:
increase the first number of mantissa bits based on determining that the error-per-bit that is greater than a set error-per-bit; and
repeatedly distribute a remaining bit based on the data size limit.

20. The electronic device of claim 16, wherein the instructions, when executed by the at least one processor individually or collectively, further cause the electronic device to generate the final level structure based on determining the level error to be minimized.
